(19) United States
(12) Patent Application Publication
(10) Pub. No.: US 2008/0136467 A1
(43) Pub. Date: Jun. 12, 2008

(54) BUFFER CHAIN DRIVER

(75) Inventors: Sotirios Tambouris, Munich (DE); Markus Dietl, Munich (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 11/939,347

(22) Filed: Nov. 13, 2007

(30) Foreign Application Priority Data
Nov. 13, 2006 (DE) 10 2006 053 322.4

(51) Int. Cl. H03K 3/00

(52) U.S. Cl. 327/111; 327/108

(57) ABSTRACT

A buffer chain driver has two similar signal paths formed by series-connected buffer cells, each comprising two series connected inverter stages in each signal path. The output of the first inverter stage in each signal path is coupled to the output of the last inverter stage in the other signal path. Cross-coupling between the two signal paths results in an interpolation in the sense that each signal path has a 50% contribution to each of the complementary output signals, thereby compensating for any mismatch between the signal paths.

This application claims priority from German Patent Application No. 10 2006 053 322.4, filed 13 Nov. 2006.

### FIELD OF THE INVENTION

The invention relates to a buffer chain driver. More particularly, but not exclusively, the present invention relates to a full-swing differential CMOS buffer stage using interpolation.

### BACKGROUND

In many applications there is a need to have a complementary full-swing clock signal driving a variable capacitive load (sometimes greater than 10 pF) connected over transmission line stubs. In order to be able to drive this high load it is necessary to build up a buffer chain.

Buffer chains formed by series-connected inverters are often implemented in CMOS technology. A conventional inverting buffer stage is shown in FIG. 1. The buffer is formed by a complementary pair of MOS transistors. The drain terminals of the transistors are interconnected and the source terminal of the n-channel transistor is connected to ground, while the source terminal of the p-channel transistor is connected to a voltage rail VDD (the power supply voltage). An output terminal is the node interconnecting the drain terminals, which is operable to output a voltage signal OUT to the input terminal of the next inverter in the chain, or to an external load. The gate terminals of both transistors are interconnected and a node interconnecting the gate terminals is operable to receive an input signal IN. Two similar chains of such inverters forming complementary paths are provided in a driver, as shown in FIG. 2, and each of the chains is operable to receive one of the complementary input signals CLK and CLKB.

In the operation of the conventional buffer chain driver shown in FIG. 2, a clock signal CLK and a complementary clock signal CLKB are input to the first and second inverter chains, or complementary paths, of the driver. The resultant output voltage signal of the driver plotted against time is shown in FIG. 3. It can be seen that the voltage crosspoint (VOX) of the signals at the output of the driver varies over time. This is caused by delay differences resulting from a transistor mismatch between the two paths or from a pMOS/nMOS mismatch of one inverter driving high or driving low. The resultant variation of VOX is amplified from buffer to buffer. Therefore the more buffers that are needed to achieve the required driving capability, the more the VOX deviation will be. This means that there will be a high slew rate variation over the capacitive load being driven by the driver, leading to unwanted high frequency components.

### SUMMARY OF THE INVENTION

The invention provides a buffer chain driver with complementary CMOS signal paths that has crosspoint stability over process, voltage and temperature variations and over frequency. In one aspect, the buffer chain driver of the invention comprises two similar signal paths formed by series-connected buffer cells, each comprising two series-connected inverter stages in each signal path. The output of the first inverter stage in each signal path is coupled to the output of the last inverter stage in the other signal path. This cross-coupling between the two signal paths results in an interpolation, in the sense that each signal path has a 50% contribution to each of the complementary output signals, thereby compensating for any mismatch between the signal paths. In this way, the voltage crosspoint VOX at the outputs from the driver remains stable and the slew rate variation over the load being driven by the voltage signal output from the driver is reduced.

In a described embodiment that has a tristate output, the buffer cells or stages are each formed by a variant of the conventional CMOS inverter. In this particular inverter, an additional pair of switching transistors is inserted between the drains of the complementary transistors, the channels of which are connected between the supply rails. The gates of these additional switching transistors receive enable signals so that the inverter stages in the chain can be enabled or disabled as required.

Preferably, each buffer stage further comprises signal correcting or smoothing circuitry to substantially eliminate unwanted high frequency components of the voltage signal output from the driver. The signal correcting circuitry can be a capacitive element and may also comprise a resistive element connected in series between the capacitive element and the load that is being driven. The signal correcting circuitry also reduces noise from the power supply that can appear on the output signal.

### BRIEF DESCRIPTION OF THE DRAWINGS

Further features and advantages of the invention will become apparent from the following description of representative example embodiments and from the accompanying drawings, wherein:

FIG. 1 (Prior Art) shows a conventional CMOS inverter;

FIG. 2 (Prior Art) shows a schematic diagram of a conventional buffer cell in a buffer chain driver;

FIG. 3 (Prior Art) is a graph of the output voltage of a conventional buffer chain driver against time;

FIG. 4 shows a buffer cell according to a first embodiment of the invention;

FIG. 5 is a timing diagram of a buffer cell according to the embodiment of FIG. 4;

FIG. 6 is a graph of output voltage against time for a buffer cell according to the embodiment of FIG. 4;

FIG. 7 is a schematic diagram of a buffer chain driver according to a second embodiment of the invention;

FIG. 8 is a graph of output voltage against time for a buffer cell according to the embodiment of FIG. 7;

FIG. 9 is a schematic diagram of a buffer chain driver with a plurality of series connected buffer cells;

FIG. 10 is a schematic diagram of a buffer cell according to a third embodiment of the invention; and

FIG. 11 is a circuit diagram of one inverter stage in the buffer cell according to the embodiment of FIG. 10.

### DETAILED DESCRIPTION OF EXAMPLE EMBODIMENTS

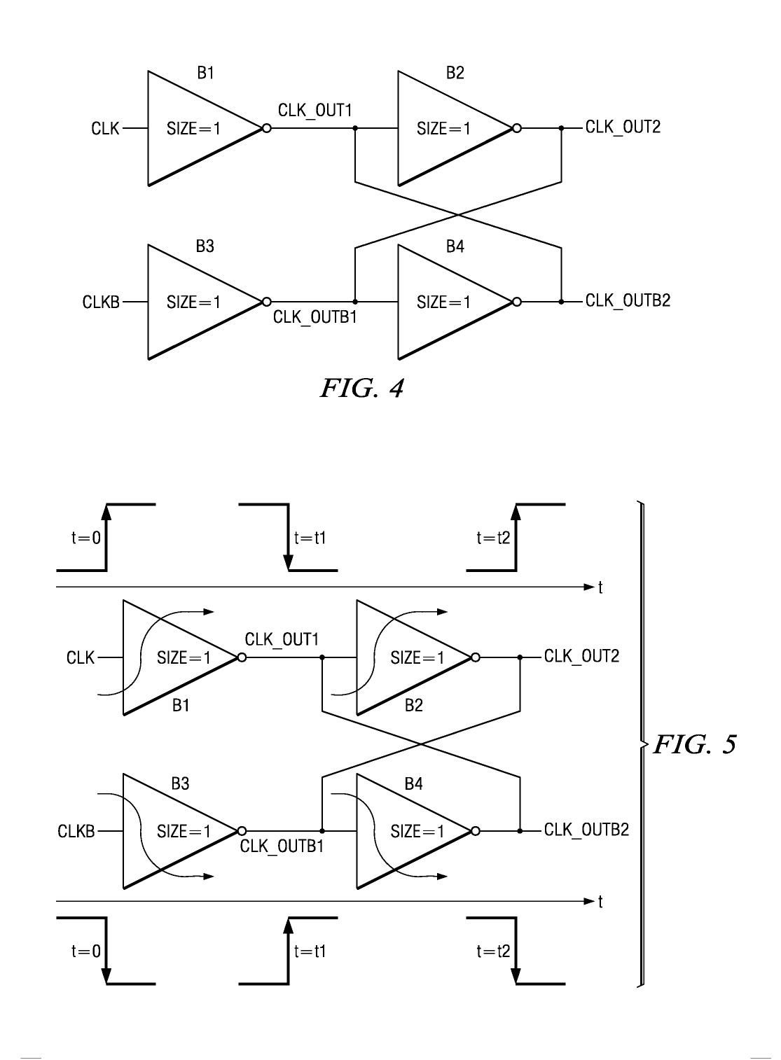

A single buffer cell of a buffer chain driver is shown in FIG. 4, which comprises a first signal chain or path having series connected inverter stages B1 and B2 and a second path arranged parallel to the first path and having series connected inverter stages B3 and B4, which are parallel to, and correspond with, the inverter stages B1 and B2, respectively.

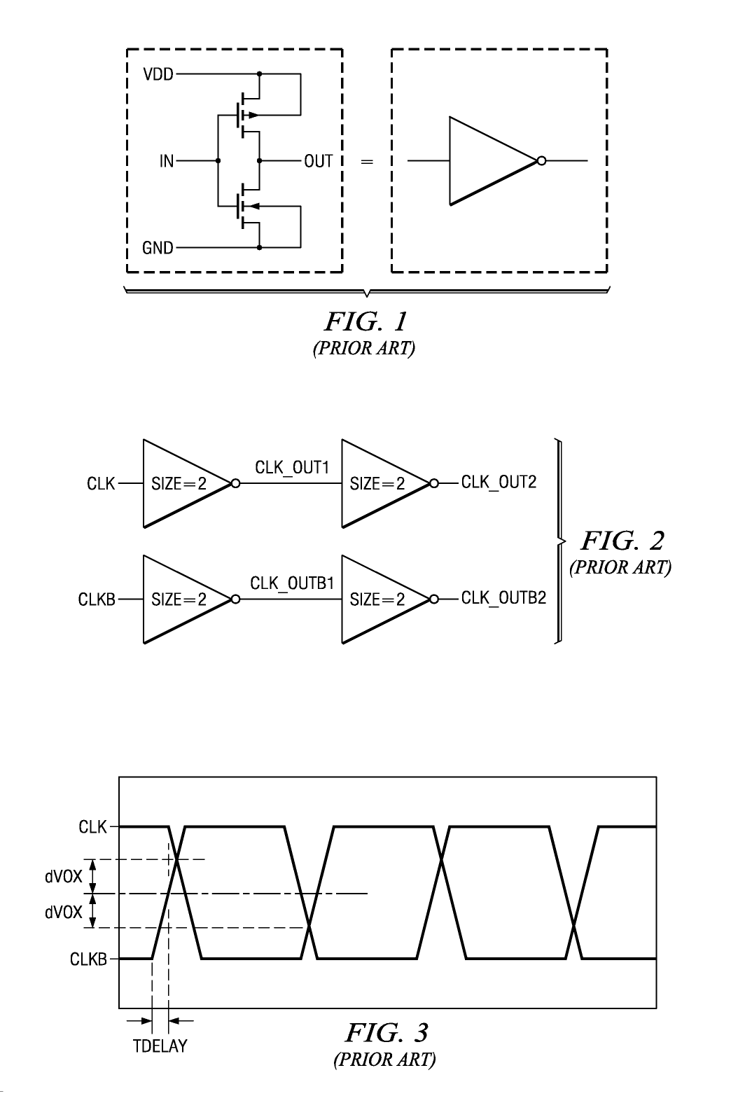

The inverter stages B1, B2, B3 and B4 are cross-coupled so that the output of inverter stage B1 is coupled with the output of inverter stage B4 and the output of inverter stage B3 is coupled with the output of inverter stage B2. The inverter stages B1, B2, B3 and B4 can, as such, be conventional as shown in FIG. 1 and can be all the same size; so each of the two output signals is a 50% contribution of both signal paths. For a given driving capability, the size of each inverter stage is only half that of a conventional buffer stage.

In operation, the input of the inverter stage B1 receives a clock signal CLK and the input of the inverter stage B3 receives a clock signal CLKB, which is complementary to the clock signal CLK. The two signal paths are thus complementary paths. The timing of the propagation of the complementary signals in each chain is shown in FIG. 5. The inverter stage B1 introduces a delay t1 to the signal CLK and outputs a signal CLK_OUT1. At the output of the inverter stage B2, a delay t2 is introduced to the signal CLK_OUT1 and a signal CLK_OUT2 is output from B2. In the complementary path formed by the parallel chain of inverter stages, the inverter stage B3 introduces a delay t1 to the signal CLKB and outputs a signal CLK_OUTB1. At the output of the inverter stage B4, a clock signal CLK_OUTB2 is output after a delay t2 to the signal CLK_OUTB1. While the delay t1 in each complementary path is due only to the delay introduced to the complementary clock signals CLK and CLKB by the first inverter stages in each path, B1 and B3, respectively, the delay t2 introduced to the clock signal in the first path having the input CLK_OUT1 is due to the delay introduced to the signal from the inverter stage B2, as well as the stages B1 and B3, and the delay t2 introduced to the clock signal CLK_OUTB1 in the second path is the delay due to the stages B3, B4 and B1.

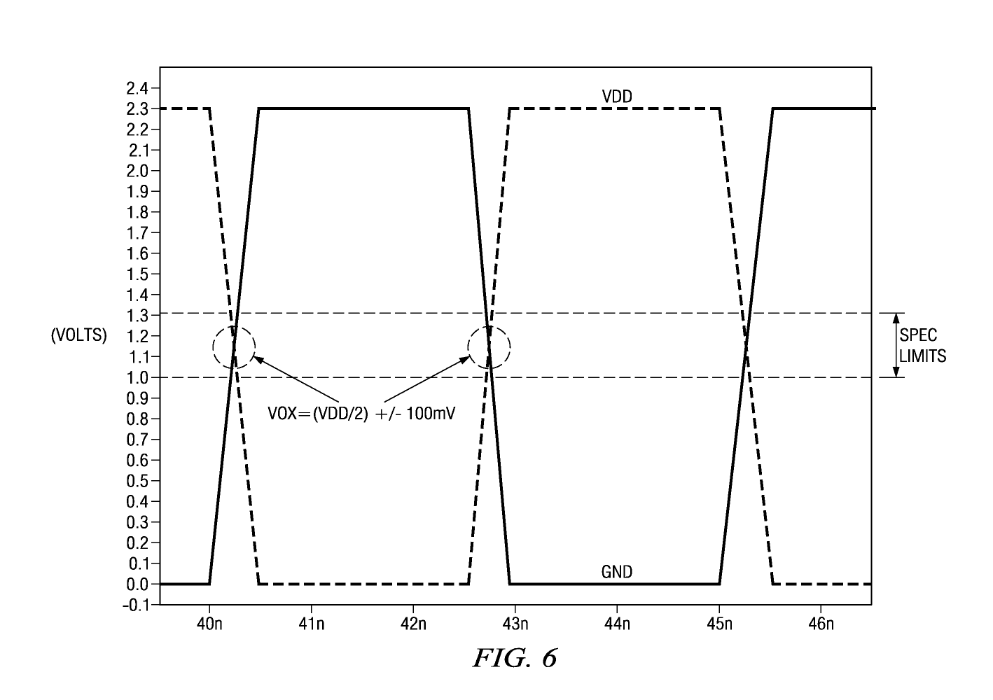

Interpolation between the chains or complementary paths can take place because of the cross-coupling between complementary paths. This means that the voltage signal output from the driver is full-swing between the voltage rail VDD and ground. The ideal value of the voltage crosspoint VOX is VDD/2, with a tolerance of +100 mV. A graph of output voltage against time for the driver shown in FIGS. 4 and 5 with a 10 pF capacitive load is shown in FIG. 6. It can be seen that the voltage crosspoint VOX remains stable with increasing time and does not drift to the high side or the low side. Interpolation of the complementary paths causes the voltage crosspoint VOX of the output signal to be compensated and consequently stable without deviation from the ideal value of VDD/2 (the spec limit is +100 mV from VDD/2). Additionally the rise and fall times between the complementary output signals CLK_OUT2 and CLK_OUTB2 are matched.

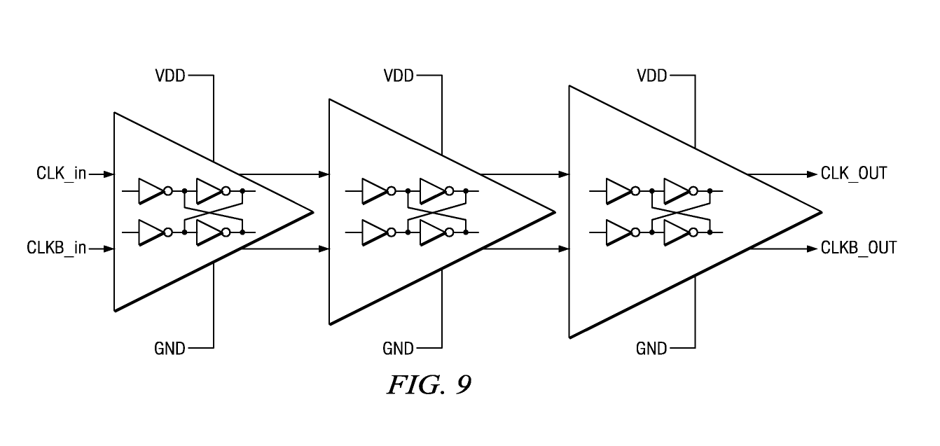

The two parallel complementary paths comprising the four inverter stages B1, B2, B3 and B4 form a single non-inverting buffer cell. To achieve the required driving capability in a given implementation, a number of appropriately sized buffer cells may be connected in series, as shown in FIG. 9. It should be noted that, if the voltage crosspoint VOX at the input of the clock signals CLK and CLK_B is far away from VDD/2, it may take several series connected buffer cells to correct the voltage crosspoint to VDD/2. As the signal passes each buffer cell, the voltage crosspoint approaches VDD/2 more closely.

By using a chain of interpolated buffer cells, the generation of power supply distortion is also cut down dramatically compared to a simple inverter with the same driver capability. This is because an inverter with the same driver capability has almost double current flowing during switching transitions. However, the buffer driver in the described embodiment switches first with half the driving capability and then after a certain delay the second half of the driving capability switches. The current spikes that are generated then are not as large as those generated by an inverter, thus leading to a lower noise distortion on the power lines. Furthermore, the slew rate variations over the capacitive load at the output of the driver are lowered and the rising slew rate is matched with the falling slew rate.

This driver can be used as a base for designing a high drive (with a current of several mA) CMOS output stage with robustness in terms of signal integrity when driving different transmission line configurations that have a receiver (capacitive load). In this case, a termination resistor is connected between the last buffer cell in the driver, in both of the parallel chains, and the load capacitance via a transmission line.

As the system impedances are in practice never perfectly matched, there will be signal reflections which cause distortion in the rising and falling edges of the output voltage signal measured at the termination resistor. When a signal is generated by the driver, it travels to the receiver input and because of the capacitive character of the receiver (load capacitor), the high frequency components will be reflected, each being frequency dependent. These reflections travel back to the driver and also to the termination resistor. The reflected wave combines with the voltage signal waveform at the termination resistor, thus leading to the above-described signal distortion, or “slope reversal” (change in direction of the slope of the voltage signal output from the driver). The amplitude of the slope reversal is determined by the value of the load capacitance.

Because the impedance of the driver and the transmission line cannot be matched and signal reflections cannot be avoided, the high frequency components of the output voltage signal itself must be minimized. The highest frequency components are mainly included when the output signal changes from HIGH to LOW, and vice versa. Therefore, to prevent high frequency components, the “edge change” of the signal should be corrected when the signal has almost reached the HIGH level voltage and also when the signal approaches the LOW level voltage.

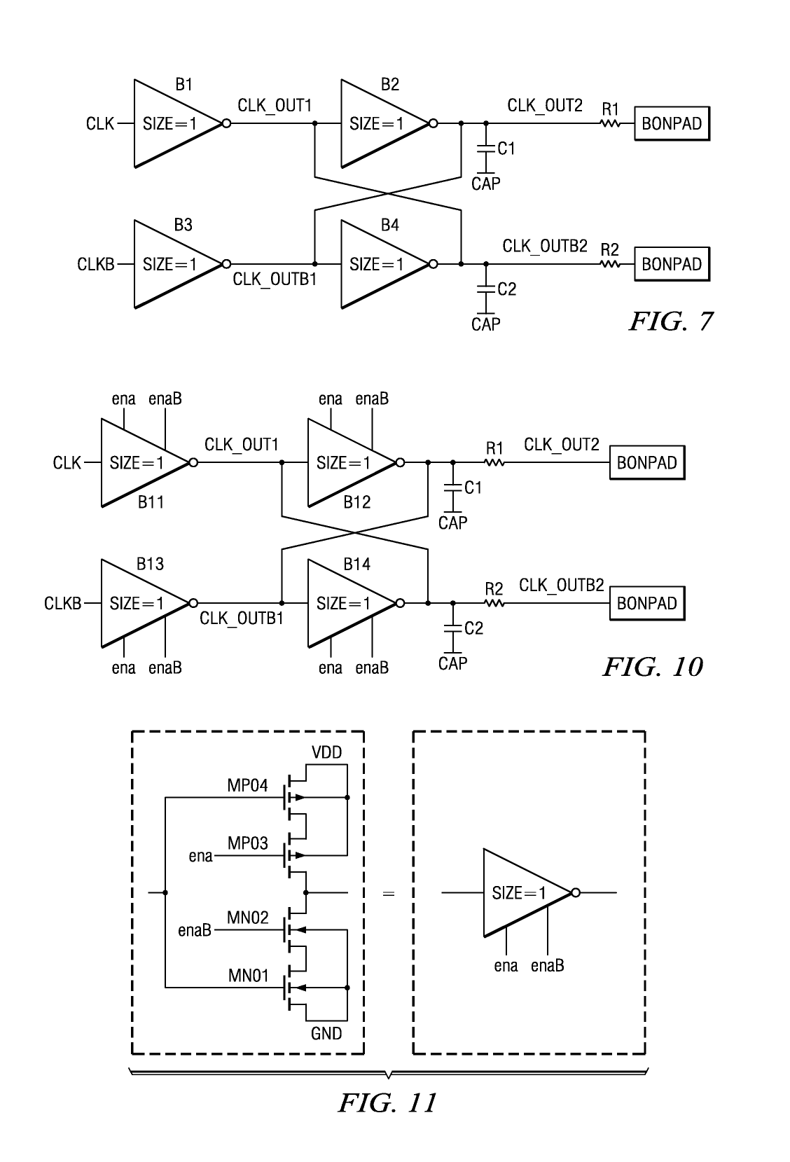

A second embodiment of the buffer cell is shown in FIG. 7, which corrects the signal when it approaches the HIGH and LOW voltage levels. The buffer cell has the same structure as that shown in the first embodiment, having inverter stages B1 and B2 connected in series in a first chain and inverter stages B3 and B4 connected in series in a second chain parallel to the first chain, forming cross-coupled parallel chains or complementary paths as in FIG. 4. In this embodiment, the output of the stage B2 is also connected to a capacitor C1 and the output of the stage B4 is connected to a capacitor C2. The capacitors C1 and C2 are also connected to ground and to resistors R1 and R2, respectively. The resistors R1 and R2 are also connected to the bond pad of the integrated circuit, which provides a connection to a transmission line. The resistance of the resistors R1 and R2 should be about a quarter of the value of the total impedance of the transmission line.

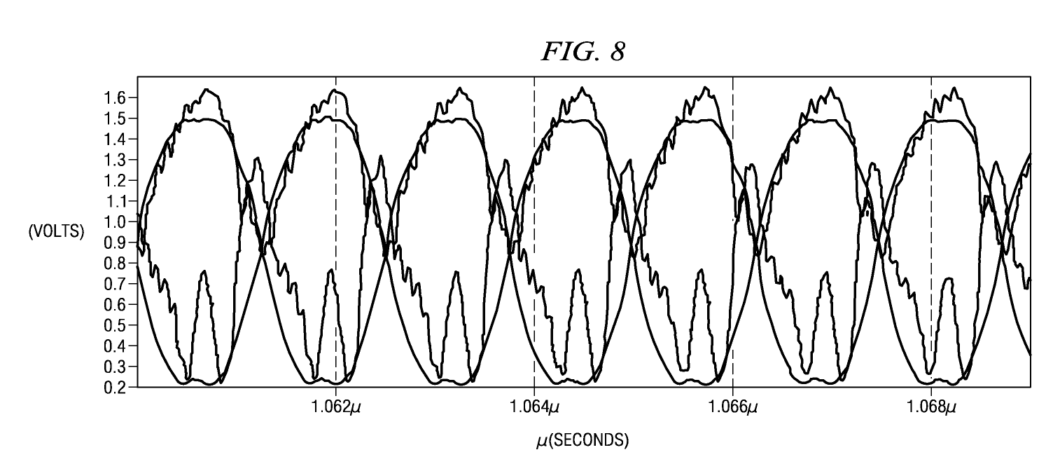

FIG. 8 shows the voltage output of the driver shown in FIG. 7, when the outputs of each buffer chain are driving a IOpF capacitive load at 400 MHz, as well as the output of a conventional inverter output driver. The presence of the capacitors C1 and C2 at the end of each buffer chain corrects or “smooths” the voltage signal as it approaches the HIGH and LOW levels. The resistors R1 and R2 connected between each capacitor and the transmission line match the impedance of the driver with the impedance of the transmission line. The required slew rate of the driver can then be reached, while maintaining the signal integrity of the voltage signal generated by the driver, and the slew rate variation of the capacitive load can be reduced.

FIG. 10 shows a further embodiment of the buffer cell where tristate outputs are provided. In this embodiment, inverter cells B11, B12 in a first signal path and inverter cells B13, B14 in a second, parallel signal path are connected in the same manner as in FIG. 7, including also the correction circuitry with the capacitors C1, C2 and resistors R1, R2. In addition, each inverter cell has complementary enable inputs ena and enaB to selectively switch the output of the inverter cell to a high impedance condition.

FIG. 11 shows the structure of one of the switchable inverter stages B11, B12, B13 or B14. The inverter stage differs from the conventional structure in FIG. 1 in that a pair of switching MOS transistors MN02, MP03 are inserted between the complementary MOS transistors MN01, MP04, both switching transistors MN02 and MP03 receiving complementary enable signals ena and enaB, respectively.

Although the present invention has been described with reference to specific embodiments, it is not limited to such embodiments. Those skilled in the art to which the invention relates will appreciate that there are other ways and modifications of ways to implement the principles of the claimed invention.

What is claimed is:

1. A buffer chain driver with two similar signal paths formed by series-connected buffer cells, each comprising two series connected inverter stages in each signal path; and
wherein the output of the first inverter stage in each signal path is coupled to the output of the last inverter stage in the other signal path.

2. The driver of claim 1, wherein each buffer cell comprises tristate inverters, each with a pair of complementary MOS transistors having their channels connected between supply rails in series with channels of a pair of switching MOS transistors, the gates of which receive enable signals (ena, enaB).

3. The driver of claim 2, wherein each buffer cell further comprises signal correcting circuitry with a capacitive element and a resistive element.

4. The driver of claim 1, wherein each buffer cell further comprises signal correcting circuitry with a capacitive element and a resistive element.
